(19) United States
(12) Patent Application Publication
(10) Pub. No.: US 2014/0270629 A1
(43) Pub. Date: Sep. 18, 2014

(54) OPTICAL WAVEGUIDE NETWORK OF AN INTERCONNECTING IC MODULE

(71) Applicant: APIC CORPORATION, Culver City, CA (US)

(72) Inventors: Birendra Dutt, Westchester, CA (US); Ashok Kumar Kapoor, Palo Alto, CA (US)

(73) Assignee: APIC Corporation, Culver City, CA (US)

(21) Appl. No.: 13/843,206

(22) Filed: Mar. 15, 2013

(51) Int. Cl. G02B 6/12; H01L 31/12; G02B 6/136

(52) U.S. Cl. CPC G02B 6/12; G02B 6/136; H01L 31/12
USPC 385/14; 438/25

(57) ABSTRACT

The subject matter disclosed herein relates to a photonic module comprising: a silicon-on-insulator (SOI) wafer; one or more photonic components on the SOI wafer; a plurality of metal pads to receive integrated circuit (IC) chips to be mounted on the SOI wafer; silicon optical waveguides to transfer optical signals among terminals of individual the IC chips, wherein the silicon optical waveguides comprise portions of the SOI wafer; and silica optical waveguides to transfer optical signals among terminals of different the IC chips.

### FIELD

The subject matter disclosed herein relates to optical-electronic systems that include optical interconnects to distribute signals to or among integrated circuits.

### BACKGROUND

Optical interconnects may be used in electronic circuits. For example, optical isolation devices may be used in mixed signal applications involving communication systems. Optical interconnect technology may also be used in applications involving edge interconnects to exchange signals among a number of integrated circuits. For example, optical interconnects may be used to communicate among integrated circuits in place of leads and copper circuit board connections.

### BRIEF DESCRIPTION OF THE DRAWINGS

Non-limiting and non-exhaustive embodiments will be described with reference to the following objects, wherein like reference numerals refer to like parts throughout the various objects unless otherwise specified.

FIGS. 1-2 are schematic block diagrams of portions of opto-electronic systems, according to various embodiments.

FIGS. 3 and 4 are cross-section views of a photonic module, according to embodiments.

FIG. 5 is a schematic diagram of a driver circuit in a photonic module, according to an embodiment.

FIG. 6 is a schematic diagram of a detector circuit in a photonic module, according to an embodiment.

FIGS. 7-8 are perspective views of a portion of a photonic module, according to embodiments.

FIGS. 9A-9D are cross-section views showing fabrication of a photonic layer of a photonic module, according to an embodiment.

FIGS. 10A-10C are cross-section views of photonic layer fabrication for a photonic module, according to an embodiment.

FIG. 11 is a cross-section view of photonic layer fabrication for a photonic module, according to an embodiment.

FIG. 12 is a flow diagram of photonic layer fabrication for a photonic module, according to an embodiment.

FIG. 13 is a perspective structural view of a double micro-ring modulator of a photonic module, according to an embodiment.

FIGS. 14 and 15 are cross-sectional structural views of a photodetector of a photonic module, according to an embodiment.

FIG. 16 is a top view of a photonic plane of a photonic module, according to an embodiment.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, methods, apparatuses, or systems that would be known by one of ordinary skill have not been described in detail so as not to obscure claimed subject matter.

Reference throughout this specification to “one embodiment” or “an embodiment” may mean that a particular feature, structure, or characteristic described in connection with a particular embodiment may be included in at least one embodiment of claimed subject matter. Thus, appearances of the phrase “in one embodiment” or “an embodiment” in various places throughout this specification are not necessarily intended to refer to the same embodiment or to any one particular embodiment described. Furthermore, it is to be understood that particular features, structures, or characteristics described may be combined in various ways in one or more embodiments. In general, of course, these and other issues may vary with the particular context of usage. Therefore, the particular context of the description or the usage of these terms may provide helpful guidance regarding inferences to be drawn for that context.

As used to describe such embodiments, terms “above”, “below”, “upper”, “lower”, “horizontal”, “vertical”, and “side” describe positions relative to an arbitrary axis of a module, for example. In particular, “above” and “below” refer to positions along an axis, wherein “above” refers to one side of an element and “below” refers to an opposite side of the element. Relative to such an “above” and “below”, “side” refers to a side of an element that is displaced from an axis, such as the periphery of a structure, for example. Further, it is understood that such terms do not necessarily refer to a direction defined by gravity or any other particular orientation reference. Instead, such terms are merely used to identify one portion versus another portion. Accordingly, “upper” and “lower” may be equivalently interchanged with “top” and “bottom”, “first” and “second”, “right” and “left”, and so on. “Horizontal” may refer to an orientation perpendicular to an axis while “vertical” may refer to an orientation parallel to the axis.

Embodiments described herein include a photonic module comprising semiconductor packaging to integrate a plurality of integrated circuit (IC) chips with electronic and optical transmission paths. For example, such a photonic module may be used to connect various VLSI IC chips with an ultra-high bandwidth, low-power optical network. A photonic module may include one or more interface IC chips to provide a uniform interface between “3^{rd} party” VLSI chips, a term well known to those skilled in the art, and a photonic network. In one implementation, an optical fiber may be used for transmitting input signals to and output signals from a photonic module.

In an embodiment, a photonic module may include a number of semiconductor layers or planes on which IC chips, photonic components, optical waveguides, and electrical conductors, among other things, reside. In one implementation, a photonic module may comprise a portion of a communication network. For example, such a network may comprise a hierarchical arrangement of components including IC chips, printed circuits boards, an equipment rack, a local area network (LAN), and a wide area network (WAN). Such components may communicate with one another via electronic and/or optical signals.

In one embodiment, a photonic module may comprise a plurality of metal pads to receive IC chips, such as CMOS chips, for example. Such IC chips may be mounted on a particular layer of a module comprising a silicon-on-insulator (SOI) wafer. Upon or after receiving electrical signals from the IC chips, electrical interface circuits may modify the electrical signals by changing any of a number of parameters of the electrical signals, such as voltage, current, frequency, and wave shape, just to name a few examples. Electrical signals, thus modified and coupled to opto-electronic components known as modulators may allow the IC chips to electronically modulate the optical signal in an adjacent waveguide.

An optical filter may subsequently isolate a particular optical wavelength signal from the waveguide and route it to a photodetector for optical to electronic conversion. Consequently, the photodetector may receive the optical wavelength signal and generate a photo-current in proportion to the intensity of the optical wavelength signal. An amplifier, which may comprise a trans-impedance amplifier (TIA), for example, may receive the photo-current to generate a voltage in proportion to the photo-current. Such an amplifier may be located on a same module layer as the IC chips of the photonic module. An electronic circuit may then convert the output of the amplifier to voltage levels appropriate for driving electronic buffers on one or more of the IC chips.

A photonic layer on the SOI wafer may comprise silicon optical waveguides and silica optical waveguides to transmit and receive optical signals for communication among the IC chips and other components of the photonic module. In some implementations, an SOI wafer may comprise silicon dioxide (SiO₂), though claimed subject matter is not limited in this respect.

In another embodiment, a photonic module may comprise an SOI wafer, one or more photonic components on the SOI wafer, and a plurality of metal pads to receive a number of IC chips to be mounted on the SOI wafer. The IC chips may be mounted face-down on the SOI wafer. In one implementation, metal pads may comprise micro-bumps or copper pillars. The photonic module may further comprise silicon optical waveguides to transfer optical signals between or among terminals of individual IC chips. In one implementation, such silicon optical waveguides may comprise portions of the SOI wafer. In addition to the silicon optical waveguides, the photonic module may further comprise silica optical waveguides to transfer optical signals among terminals of different the IC chips, for example. Silicon optical waveguides and silica optical waveguides may be formed on a same SOI wafer. A plurality of optical interfaces on the SOI wafer may interconnect silicon optical waveguides and silica optical waveguides. In one implementation, a cladding layer comprising silicon dioxide (SiO₂) may cover silicon optical waveguides and silica optical waveguides.

In yet another embodiment, a photonic module may comprise an SOI wafer, one or more photonic components in a first layer on the SOI wafer, and a plurality of IC chips mounted in a separate layer on the SOI wafer which is electrically and optically isolated from the SOI wafer. The photonic module may further comprise an interface chip to modify voltages of electronic signals communicated among the plurality of IC chips and the one or more buffers driving the photonic components. In an example implementation, the interface chip may be flip bonded on the SOI wafer at a same level as the IC chips.

In an embodiment, a photonic module may be fabricated by forming a plurality of optical resonators, optical modulators, diode lasers, and/or optical filters on an SOI wafer, and etching a portion of the SOI wafer to form silicon optical waveguides. In an implementation, silica optical waveguides may be formed on the SOI wafer so that the silica optical waveguides may interconnect with the silicon optical waveguides so as to enable transfer of optical signals between silica and silicon optical waveguides.

In another embodiment, a photonic module may be fabricated by etching an SOI wafer to establish locations of a plurality of photonic components including silicon optical waveguide, and processed further by depositing a silicon dioxide film including germanium-oxide doping on the etched SOI layer, and annealing the silicon dioxide-based film to form a silica layer. The concentration of germanium oxide in the silica layer may be varied. The silica layer may be patterned by lithography and etching to form a silica optical waveguide coupled to the silicon optical waveguides at various locations on the SOI wafer, for example. In an alternate embodiment, other methods to form silica waveguide can be used. In yet another embodiment, materials with optical properties similar to silica such as organic optical polymers, can be used to form waveguides on SOI wafer.

FIG. 1 is a schematic block diagram of a portion of an opto-electronic system 200, according to an embodiment. For example, system 200 may include a photonic module 205. Block arrows in FIG. 1 indicate a general signal flow in an example implementation. System 200 may include an external optical fiber 210 to provide an optical signal to photonic module 205. In particular, photonic module 205 may receive the optical signal from the fiber 210 via an optical coupler 220 to the silica waveguide 230. A silica waveguide 230 may subsequently transmit optical signals to various portions of photonic module 205, as indicated by block arrows 240.

In one implementation, photonic module 205 may include IC chip portion 250 including one or more IC chips, fabricated with CMOS technology. However, chips fabricated with other types of technologies such as bipolar, BiCMOS, compound semiconductors and device types such as TTL, PMOS, NMOS, ECL, HBT, MESFET and so on may be used. IC chip portion 250 may also include photonic module 252 including silicon waveguides to transmit optical signals over relatively short distances within IC chip portion 250. Accordingly, optical signals transmitted by silica waveguides 230 may be transferred or coupled into silicon waveguides in 252 at an edge of the IC chip portion 250. Within IC chip portion 250, silicon waveguides in 252 transmit optical signals between or among various photonic components and converts them in electrical signals. IC chip 250 may operate using the said electrical signals. Accordingly, such photonic components may be used to convert optical signals transmitted by optical module 252 to electrical signals used by the IC chips. The electrical signal may be processed by the electrical chip 250 and converted to optical signal using 252. This signal may be coupled to silica waveguide 260.

Further, photonic module 205 may include any number of additional IC chip portions, such as IC chip portion 280, for example. As for IC chip portion 250, 280 may also include photonic module 282 to transmit optical signals over relatively short distances within IC chip portion 280, for example. Silica waveguides 260 may be used to transmit optical signals between or among IC chip portions (e.g., 250 and 280) over relatively long distance, such as over about 100.0 millimeters, for example. Accordingly, optical signals transmitted by silica waveguides 260 may be transferred or coupled into silicon waveguides 282 at an edge of the IC chip portion 280. Within IC chip portion 280, silicon waveguides 282 transmit optical signals between or among various photonic components, which may be used to convert optical signals transmitted by photonic module 282 to electrical signals used by the IC chips. Electrical power and/or ground may be provided to IC chip portions 250 and 280 by block 270, for example.

One or more IC chip portions may produce an output optical signal that may be coupled into silica waveguides 235. Photonic module 205 may subsequently provide an optical signal to an external output cable 215 via an optical coupler 225.

FIG. 2 is a schematic block diagram of a portion of an opto-electronic system 300, according to an embodiment. For example, system 300 may comprise a photonic module configured to interconnect with a VLSI chip (not shown). Such a VLSI chip may comprise an interface portion 310 including input/output ports of CMOS chips, in one example implementation. The interface portion 310 may connect to an interface chip 311. For example, such an interface chip may comprise an electrical interface circuit portion to receive a plurality of electrical signals from individual CMOS IC chips and to modify voltages of the electrical signals, and an optical transmitter portion to convert the modified electrical signals to optical signals and to provide the optical signals to one or more photonic drivers. As described below, the interface chip may also comprise optical waveguides among the CMOS IC chips, and an optical receiver portion to convert optical signals in the optical waveguides to electrical signals and to amplify the electrical signals to voltage levels for operating the CMOS IC chips. Of course, such details of an interface portion are merely examples, and claimed subject matter is not so limited.

The interface chip 311 may comprise an electrical portion 320 and a photonic portion 330. The electrical portion 320 may exist in form of a separate chip which is placed on SOI board in close vicinity to the CMOS chip. Photonic portion 330 may exist as a set of photonic components on the SOI wafer. Electrical connections between 320 and 330 may exist to perform the required functions. For example, electrical portion 320 of the interface chip may connect with high speed signal pins on the interface portion of a VLSI chip via an electrical interface circuit 324. Low speed, non-critical signal pins on 310 may connect with interface chip 311 using circuit 322. Portion 324 may comprise a CMOS chip 326. CMOS chip 326 may comprise drivers 328 and detectors 327. Driver 328 may comprise buffers and other circuit blocks. Detector 327 may contain amplifiers and other circuit blocks. Photonic portion 330 may include modulators, waveguides, etc. in portion 331 to interface with driver 328. Photonic portion of 330 may also include optical filters, and/or photodiodes to connect with detector 327.

FIG. 3 is a cross-section view of a photonic module 600, according to an embodiment. Photonic module 600 may comprise an SOI wafer 605 and one or more photonic components 642 on the SOI wafer. Components 642 may be located under IC chips 630 and/or 635, which may be flip bonded on the SOI wafer. Micro-bumps 634 may be used to electrically connect IC chips to circuitry on wafer 605, for example. IC chips 630 and 635 may comprise CMOS chips, memory, single or multi core processors, and/or hyper memory cubes, for example. A heatsink 631 may be located on any number of IC chips, for example.

SOI wafer 605 may be fabricated on a silicon substrate 608. An optical cable 610 may provide an optical signal to module 600 via couplers 620, for example. A temperature controller module 657 may be located on wafer 605, for example.

Silicon waveguides 660 may comprise a portion of SOI wafer 605. In other words, waveguides 660 may be fabricated from material of SOI wafer 605. Silicon waveguides 660 may be used to transmit optical signals relatively short distances, such as between or among connections of single IC chips 630 or 635. On the other hand, silica waveguides 650 may be used to transmit optical signals relatively long distances, such as between or among different IC chips 630 or 635. Substrate 608 may include ball-grid-array (BGA) balls 615 for mounting the substrate to another module, for example. Wafer 605 may include flip chip bumps 628, and through-wafer vias (TWVs) 625, which may comprise through-silicon vias (TSVs) in some implementations. Such vias may connect optical drivers and metallic lines, and may form a low resistance electrical connection between terminals of the optical drivers and the metal lines. In one implementation, TWVs may connect to IC chips to provide power and/or grounding to the IC chips, for example. Of course, such details of photonic module 600 are merely examples, and claimed subject matter is not so limited.

FIG. 4 is a cross-section view of a photonic multi-chip-module (PMCM) 700, according to another embodiment. PMCM 700 may comprise a photonic module 705 and IC chips 730, 735, and 738, which may be flip bonded on the photonic module. IC chip 738 may comprise a processor, while IC chips 730 and 735 may comprise hyper memory cubes, for example. Micro-bumps 734 may be used to electrically connect IC chips to circuitry on wafer 705, for example. A heatsink 731 may be located on any number of IC chips, for example.

PMCM 705 may comprise an SOI wafer 706. Multiple photonic structures such as waveguides, modulators, detectors, filters may be fabricated on a SOI substrate 706. An optical cable 710 may provide an optical signal to module 700 via couplers 720, for example. Silicon waveguides 760 may comprise a portion of SOI wafer 706. Silicon waveguides 760 may be used to transmit optical signals relatively short distances, such as between or among connections of single IC chips 730 or 735. On the other hand, silica waveguides 750 may be used to transmit optical signals relatively long distances, such as between or among different IC chips 730 or 735. On-chip laser 780 may be placed on the SOI wafer using techniques known to those skilled in the art and coupled to waveguide 790.

Photonic module 705 may be packaged in a substrate 708. For example, ball grid array packaging technology may be used to package photonic module 705. Substrate 708 may include BGA balls 715 for mounting the substrate to another module, for example. Wafer 705 may include flip chip bumps 728, and through-wafer vias (TWVs) 725. Known to those skilled in the art, through wafer via (TWV) are also known as through silicon via (TS). Redistribution layers 712 may be used to transfer electrical signals to various portions or layers of module 700. Redistribution layers 712 may comprise metallic or semiconductor materials with relatively low electrical resistance, for example copper or alloys of copper.

In an alternate embodiment of the invention, incoming and outgoing signals may be brought in to the photonic plane 705 through the substrate 708 from balls 715, through the redistribution layer 712, through flip chip bumps 728 and TWV 725.

FIG. 3 shows an alternate embodiment of the packaging scheme for the photonic module 605, which is the same as module 705. A novelty of the packaging scheme shown in FIG. 3 lies in, for example, arranging the connection between power and ground pins needed to operate the module 605 via the pad 690 at the edge of the substrate 608, and wire bonded 691. External signal input and output may also be constructed with optical fiber 610 as well wire bonded using the scheme shown here with portions 690 and 691.

FIG. 5 is a schematic diagram of a driver circuit 800 in a photonic module, according to an embodiment. Laser source 810 may generate an optical signal, which may comprise a number of wavelength or frequency bands. The optical signal may be coupled into a silicon waveguide 830. A plurality of modulator rings 851-854 may modulate individual wavelength bands. For example, individual modulator rings may modulate a particular wavelength of the optical signal. Such modulation by an individual ring may be based on a particular electrical signal that is intended to be converted into an optical signal and transmitted through one of the waveguides 861-864. Such an electrical signal may be generated by an electrical circuit comprising a buffer or amplifier 850. The modulated photonic signals from waveguides 861-864 may be coupled to a single waveguide and this waveguide may be used to carry the signal to the desired destination on the photonic plane 805. Any number of optical rings may be employed. In one implementation, the modulator rings may be located on a photonic plane 805 of a photonic module, whereas amplifier 850 may be located on a CMOS plane of the photonic module, for example.

This figure illustrates one scheme for modulation of photonic signals. Other photonic schemes using multiple lasers to generate multiple wavelength optical signals and alternate modulation schemes, such as those using Mach Zehnder Interferometer or quantum confined stark effect based modulators may also be used.

FIG. 6 is a schematic diagram of a detector circuit 900 in a photonic module, according to an embodiment. Portion 905 represents a section of an optical module. Portion 930 represents a waveguide containing data coded in multiple wavelengths from the modulator using wavelength division multiplexing. A plurality of optical filters 951-954 may partition an optical signal in waveguide 930 into individual wavelength bands. For example, individual filters may partition or isolate a particular wavelength from the optical signal, which may include multiple individually modulated wavelength bands. Optimum number of filters may equal the number of wavelengths multiplexed in the waveguide. Optical signals comprising individual partitioned wavelength bands may be provided to a photodetector 950 to convert the optical signals to photocurrents in proportion to the intensities of the particular wavelength bands. One photodetector is used for every wavelength. For example, a waveguide containing optical signal with 8 wavelengths would require 8 filters and 0 photodetectors, although only one photodetector is shown in this figure. In one implementation, the filters may be located on a photonic plane 905 of a photonic module, whereas photodetector 950 may be located on a CMOS plane of the photonic module, for example. Of course, such details of detector circuit 900 are merely examples, and claimed subject matter is not so limited.

FIG. 7 is a perspective view of a portion of a photonic module 1000, according to an embodiment. For example, photonic module 1000 may comprise an SOI wafer 1005 and one or more photonic components, such as diode lasers 1020 and 1025, for example, on the SOI wafer. SOI waver 1005 may comprise silicon substrate 1008, buried oxide layer (BOX) 1001 and SOI layer 1003 which has been etched and converted in multiple photonic elements such as diodes 1020 and 1025 and modulator 1030, etc. SOI layer 1003 is not visible in the drawing because it has been etched and converted in elements mentioned above. In one implementation, diode lasers may be integrated with SOI wafer 1005. Module layer 1006, which may comprise a photonic layer surface, may include metal pads 1070, to which may IC chips may be flip bonded and mounted. Such IC chips may comprise ASIC, FPGA, memory, single or multi core processors, and/or hyper memory cubes, for example.

Silicon waveguides and/or silica waveguides 1060 may be located on SOI wafer 1005. Such waveguides may be used to transmit optical data signals. For example, optical signals from diode lasers 1020 and 1025 may be coupled into SOI waveguide 1061. Modulator section 1030 may include a plurality of modulator rings 1036 to modulate individual wavelength bands of the optical signals from the diode lasers. Modulator section 1030 may be located on SOI wafer 1005. For example, individual modulator rings may modulate a particular wavelength of the optical signal. Such modulation of an individual ring may be based, at least in part, on a particular electrical signal that may be provided to modulator section 1030 by a first via 1032, a second via 1042, and a third via 1052 penetrating dielectric layers 1002, 1004, and 1006. Such vias may be used to interconnect a plurality of electrical connections between electronic and photonic components. A first metal pad 1034 may be located on a surface of module layer 1002 to electrically connect first via 1032 to a third via 1042 penetrating module layer 1004. Similarly, a second metal pad 1044 may be located on a surface of module layer 1004 to electrically connect third via 1042 to a fourth via 1052 penetrating module layer 1006. Fourth via 1052 may be electrically connected to one or more metal pads 1070, for example. This represents one electrical connection between the metal pad 0970 and one contact on the modulator 1030. Similar path is formed from the second terminal 1036 of the modulator and second pad. Of course, such details of a photonic module are merely examples, and claimed subject matter is not so limited.

FIG. 8 is a perspective view of a portion of a photonic module 1100, according to an embodiment. For example, photonic module 1100 may comprise the same components and structure as photonic module 1000 except for the addition of an IC chip layer 1120 mounted to plurality of metal pads 1070 on a surface of layer 1006. For example, IC chip layer may comprise a plurality of CMOS IC chips, which may be flip bonded and mounted to metal pads 1070. IC chips of layer 1120 may be mounted to metal pads 1070 via micro-bumps 1115.

FIGS. 9A-9D are cross-section views showing fabrication of a photonic layer 1300 of a photonic module, according to an embodiment. Photonic elements may be fabricated on an SOI wafer 1305. An SOI wafer may provide a platform for such a photonic layer, allowing fabrication using semiconductor process technology, for example. Photonic elements may comprise resonators 1310, modulators 1320, optical filters 1330, and waveguides 1340, just to name a few examples. Additional photonic components may comprise optical fiber couplers 1350 and silica waveguides 1360, which may be used for inter-IC chip communications, as described above, for example.

In addition, diode lasers 1370 may be fabricated on SOI wafer 1305. For example, such diode lasers may comprise germanium diode lasers, which may be formed on SOI wafer 1305 by depositing single crystalline germanium and/or its alloys onto the SOI wafer using semiconductor process technology. In an alternative embodiment, laser built with compound semiconductors may be coupled to the SOI wafer to deliver the desired functionality as stated above. Photodetectors 1380 may similarly be formed on SOI wafer 1305.

Through-silicon-vias (TSVs) 1390 may be formed by etching holes in SOI wafer 1305 and at least partially filling the holes with an electrically conductive material such as copper. Fabrication of TSVs and photonic components may be performed in multiple process sequences to achieve similar performance of photonic elements, and claimed subject matter is not limited in this respect.

In an embodiment, micro-bumps may be added to IC chips that are to be mounted or bonded to photonic layer 1300. For example, micro-bumps may be added to a CMOS processor or hyper-memory cube IC. Such ICs may then be mounted onto photonic layer 1300. A resulting configuration may be similar to SOI wafer 705 of photonic module 700 shown in FIG. 4, for example.

FIGS. 10A-10C and 11 are cross-section views of photonic layer fabrication for a photonic module, according to an embodiment. An SOI layer 1420 comprising a substrate layer 1408, box layer 1410 and SOI layer 1420 may be used as a starting material. For example, SOI layer 1420 may be about 220 nanometers thick, and box layer 1410 may be about 2 micrometers, though claimed subject matter is not limited to such values.

In FIG. 10B, SOI layer 1420 may be patterned and etched to define a plurality of photonic components on the SOI layer. Accordingly, SOI layer 1420 may be patterned and etched to arrive at patterned SOI layer 1430. Subsequently, silicon dioxide (SiO₂) 1440 may be deposited over the structure shown in FIG. 10B to arrive at the structure shown in FIG. 10C. For an example, the silicon dioxide may be about 2.0 or 3.0 micrometers thick. Silicon dioxide 1440 may be doped with predetermined quantity of germanium dioxide (GeO₂). As explained below, this layer of silicon dioxide may be heat treated to temperatures between 900° C. and 1100° C. for 10 minutes to 2 hours to form silica layer.

In FIG. 11, silica 1440 may be patterned and etched to form resulting structure 1540, which may be about 2.0 or 3.0 micrometers thick. In the next step, Ridge structure 1545 may also be formed by patterning and etching SOI film 1430. This ridge structure 1545 may be selectively doped with N and P type impurities which will be used as optical modulators.

FIG. 12 is a flow diagram of a process 1600 for photonic layer fabrication for a photonic module, according to an embodiment. At block 1610, and as described for the embodiment shown in FIGS. 9A-9D, a plurality of optical components may be formed on an SOI wafer. At block 1620, a portion of the SOI wafer may be etched to form silicon optical waveguides on the SOI wafer. At block 1630, and as described for the embodiment shown in FIGS. 10A-10C, silica optical waveguides may be formed on the SOI wafer. Of course, such details of a process 1600 for fabricating a photonic module are merely examples, and claimed subject matter is not so limited.

In another embodiment, a process for fabricating a photonic module may comprise etching an SOI wafer to establish locations of a plurality of photonic components and to form silicon optical waveguides, depositing a silicon dioxide film including germanium-oxide doping on the etched SOI layer, annealing the silicon dioxide-based film to form a silica layer, and patterning the silica layer by lithography and etching to form a silica optical waveguide coupled to the silicon optical waveguides. Such a process may further comprise etching portions of the silicon optical waveguides to form bases for the plurality of photonic components. In one implementation, a process may further comprise etching patterns in a silicon layer on the SOI wafer to form the silicon optical waveguides, a plurality of optical modulators, and or a plurality of optical filters, for example. In another implementation, a process may further comprise depositing germanium on the SOI wafer and doping the germanium to form a plurality of photodetectors comprising germanium diodes. Of course, such details of a process for fabricating a photonic module are merely examples, and claimed subject matter is not so limited.

FIG. 13 is a perspective structural view of a ridge structure 1800 for a double micro-ring modulator of a photonic module, according to an embodiment. Though some dimensions are shown, these dimensions are merely examples, and claimed subject matter is not so limited. Central region 1845 may comprise p-doped silicon dioxide, which may be similar to ridge structure 1545 shown in FIG. 11. Peripheral regions 1860 and 1870 may comprise silicide structures. These peripheral regions may be used to fabricate optical single and double micro-ring modulators, well known to those skilled in the art.

The terms, “and,” “and/or,” and “or” as used herein may include a variety of meanings that also is expected to depend at least in part upon the context in which such terms are used. Typically, “or” as well as “and/or” if used to associate a list, such as A, B or C, is intended to mean A, B, and C, here used in the inclusive sense, as well as A, B or C, here used in the exclusive sense. In addition, the term “one or more” as used herein may be used to describe any feature, structure, or characteristic in the singular or may be used to describe some combination of features, structures, or characteristics. Though, it should be noted that this is merely an illustrative example and claimed subject matter is not limited to this example.

While there has been illustrated and described what are presently considered to be example embodiments, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular embodiments disclosed, but that such claimed subject matter may also include all embodiments falling within the scope of the appended claims, and equivalents thereof.

What is claimed is:

1. A photonic module comprising:
a silicon-on-insulator (SOI) wafer;
one or more photonic components on said SOI wafer;
a plurality of metal pads to receive integrated circuit (IC) chips to be mounted on said SOI wafer;
silicon optical waveguides to transfer optical signals among terminals of individual said IC chips, wherein said silicon optical waveguides comprise portions of said SOI wafer; and
silica optical waveguides to transfer optical signals among terminals of different said IC chips.

2. The photonic module of claim 1, wherein said silicon optical waveguides and said silica optical waveguides are formed on a same module layer as one another.

3. The photonic module of claim 1, further comprising a plurality of optical interfaces interconnecting said silicon optical waveguides and said silica optical waveguides to transfer optical signals among said silicon optical waveguides and said silica optical waveguides.

4. The photonic module of claim 1, wherein at least one of said silica optical waveguides are greater than about 100.0 millimeters long.

5. The photonic module of claim 1, wherein said plurality of metal pads are configured to receive said IC chips so as to be mounted face-down to said 501 wafer via micro-bumps.

6. The photonic module of claim 1, wherein said silicon optical waveguides are located so as to be between said SOI wafer and said individual IC chips.

7. The photonic module of claim 1, wherein said IC chips comprise multi-core processors, VLSI chips, and/or hyper memory cubes.

8. The photonic module of claim 1, further comprising through-wafer-vias (TWVs) penetrating said SOI wafer and at least partially filled with copper to provide low resistance contacts between a top surface and a bottom surface of said TWVs.

9. The photonic module of claim 8, wherein said TWVs connect to said IC chips to provide power and/or grounding to said IC chips from a substrate below said SOI wafer.

10. The photonic module of claim 1, further comprising a plurality of photonic interconnects interconnecting said photonic components, wherein said photonic interconnects are located on a single wafer layer.

11. The photonic module of claim 1, wherein said one or more photonic components comprise diode lasers, resonators, or detectors.

12. The photonic module of claim 1, further comprising an optical-electrical-optical (OEO) interface to:
receive optical signals from an external source;
modify a polarization of said optical signals; and
provide the modified optical signals to said silica optical waveguides.

13. The photonic module of claim 12, further comprising:
a photonic plane comprising said OEO interface, said SOI and silica optical waveguides, and said one or more photonic components; and
a CMOS plane comprising said plurality of metal pads to receive said IC chips.

14. The photonic module of claim 13, wherein said photonic plane and said plane are disposed on said SOI wafer.

15. A method of fabricating a photonic module, the method comprising:
forming a plurality of optical resonators, optical modulators, diode lasers, and/or optical filters on a silicon-on-insulator (SOI) wafer;
etching a portion of said SOI wafer to form silicon optical waveguides; and
forming silica optical waveguides on said SOI wafer, so that said silica optical waveguides interconnect with said silicon optical waveguides.

16. The method of claim 15, further comprising mounting a plurality of CMOS integrated circuit (IC) chips face-down to a first side of said SOI wafer via micro-bumps.

17. The method of claim 16, further comprising electrically attaching a ball-grid-array (BGA) package to a second side of said SOI wafer opposite to said first side.

18. The method of claim 17, further comprising etching said SOI wafer to form through-wafer-vias (TWVs) penetrating said SOI wafer and at least partially filled with copper to provide low resistance contacts between a top surface and a bottom surface of said TWVs.

19. The method of claim 18, wherein said TWVs interconnect said BGA package with said plurality of CMOS IC chips to transmit power/ground signals.

20. The method of claim 16, wherein said silicon optical waveguides are located between said SOI wafer and individual ones of said plurality of CMOS IC chips.

21. A method of fabricating a photonic module, the method comprising:
etching a silicon-on-insulator (SOI) wafer to establish locations of a plurality of photonic components and to form silicon optical waveguides;
depositing a silicon dioxide film including germanium-oxide doping on the etched SOI layer;
annealing said silicon dioxide-based film to form a silica layer; and
patterning said silica layer by lithography and etching to form a silica optical waveguide coupled to said silicon optical waveguides.

22. The method of claim 21, further comprising:
etching portions of said silicon optical waveguides to form bases for said plurality of photonic components.

23. The method of claim 21, further comprising:
etching patterns in a silicon layer on said SOI wafer to form said silicon optical waveguides.

24. The method of claim 21, further comprising:
etching patterns in a silicon layer on said SOI wafer to form a plurality of optical modulators.

25. The method of claim 21, further comprising:
etching patterns in a silicon layer on said SOI wafer to form a plurality of optical filters.

26. The method of claim 21, further comprising:
depositing germanium on said SOI wafer and doping said germanium to form a plurality of photodetectors comprising germanium diodes.
